(19) United States
(12) Patent Application Publication
(10) Pub. No.: US 2017/0271317 A1
(43) Pub. Date: Sep. 21, 2017

(54) INTEGRATED CIRCUIT, AND DESIGN METHOD, DESIGN APPARATUS AND DESIGN PROGRAM FOR INTEGRATED CIRCUIT

(71) Applicant: NEC Corporation, Tokyo (JP)

(72) Inventor: Takashi GOTOU, Tokyo (JP)

(21) Appl. No.: 15/458,247

(22) Filed: Mar. 14, 2017

(30) Foreign Application Priority Data
Mar. 15, 2016 (JP) 2016-051068

(51) Int. Cl. H01L 27/02; G06F 17/50; H01L 23/522; H01L 23/528; H01L 27/06; H01L 23/535

(52) U.S. Cl. CPC H01L 27/0207; H01L 27/0629; H01L 23/535; H01L 23/5226; H01L 23/528; H01L 23/5222; G06F 17/5077; G06F 17/5072

(57) ABSTRACT

Disclosed is an integrated circuit that enables the addition of larger amount of capacitance to the integrated circuit itself. The integrated circuit includes a default cell and a blank cell. When the default cell is arranged in an empty portion of the integrated circuit and a wiring of the arranged default cell is short circuited with a wiring of the integrated circuit, the blank cell is arranged instead of the arranged default cell, a wiring for coupling one terminal of the capacitance of the blank cell to the power supply terminal of the blank cell or a wiring for coupling another terminal of the capacitance of the blank cell to the ground terminal of the blank cell at the short circuited portion is arranged bypassing the wiring of the integrated circuit.

This application is based upon and claims the benefit of priority from Japanese Patent Application No. 2016-051068, filed on Mar. 15 And 2016, the disclosure of which is incorporated herein in its entirety by reference.

### TECHNICAL FIELD

The present invention relates to an integrated circuit, and a design method, a design apparatus and a design program for the integrated circuit. In particular, the present invention relates to an integrated circuit quipped with on-chip decoupling capacitors, and a design method, a design apparatus and a design program for the integrated circuit.

### BACKGROUND ART

When a large scale integration (LSI) produced using microscopic patterns and configured to operate at a high speed is designed, such an LSI sometimes needs a configuration in which on-chip decoupling capacitors are arranged in the LSI. The on-chip decoupling capacitor is a capacitor that, in order to absorb noise, such as voltage variations, that occurs on a power supply line, that is, a wiring coupled to a power supply terminal of an LSI, by utilizing the charging/discharging function of a capacitor, is disposed on the power supply line. Specifically, the above configuration is achieved by, in the LSI, arranging a large number of cells in each of which the gate node of a metal oxide semiconductor (MOS) transistor is coupled to a power supply voltage (VDD), and the source and the drain nodes thereof are coupled to ground (GND). Such cells, that is, cells each having the function of the on-chip decoupling capacitor and having no logical function, will be each referred to as an on-chip decoupling capacitor cell. The on-chip decoupling capacitor cell will be hereinafter abbreviated to a capacitor cell.

As a method for mounting such capacitor cells in an LSI, there is a method in which preliminarily prepared capacitor cells each including a specific wiring pattern are spread before the execution of layout design of logic circuits. Further, there is also a method in which preliminarily prepared capacitor cells are spread in empty regions of an LSI after the execution of the layout design of logic circuits. The former method, in which the capacitor cells are spread before the execution of the layout design of logic circuits, is likely to allow capacitor cells whose number is more than an actually required number to be inserted in view of safety because required capacitor cells are determined and spread in a way involving a certain degree of prediction. For this reason, when subsequent layout design is carried out, resources (consumed memory and processing speed) of a layout tool are likely to become worse.

Meanwhile, in the latter method, in which the capacitor cells are spread after the execution of the layout design of logic circuits, the number of required capacitor cells is obtained using a power supply analysis tool on the basis of an actual layout of the logic circuits. In this case, however, in regions where an arranged wiring density is high, wirings inside the capacitor cells interfere with wirings for logic integrated circuits and, as a result, a sufficient number of capacitor cells are difficult to arrange. For this reason, after the completion of the layout design of logic circuits, in order to reduce the density of wirings having already been designed and arranged, rework, such as the change of the layout of logic circuits, arises. Further, extra spaces need to be secured in the vicinity of individual wirings. As a result of securing the extra spaces, the chip size of the LSI may be increased.

### RELATED ART DOCUMENTS

### Patent Documents

[Patent document 1] Japanese Unexamined Patent Application Publication No. 2005-276970

[Patent document 2] Japanese Unexamined Patent Application Publication No. 2011-035210

[Patent document 3] Japanese Unexamined Patent Application Publication No. 2002-288253

### NON-PATENT DOCUMENTS

[Non-patent document 1] “Principles of CMOS VLSI design: a system perspective”, second edition, Maruzen Co., Ltd., ISBN 4-621-03294-1, p. 115, table 4.5.

### SUMMARY OF THE INVENTION

There exists a method, such as a method disclosed in patent document 1 (Japanese Unexamined Patent Application Publication No. 2005-276970), in which a plurality of decoupling capacitor cells each including a plurality of wiring pattern are prepared in advance, and capacitor cells each including patterns that do not interfere with any one of wirings for logic integrated circuits are selected and arranged. In such a case, however, capacitor cells covering all combinations of wiring patterns are difficult to prepare in advance, and as a result, a situation in which the arrangement of a sufficient number of capacitor cells is difficult has sometimes occurred.

Further, in patent document 2 (Japanese Unexamined Patent Application Publication No. 2011-035210), a configuration that, in order to use an already arranged capacitor cell as a cell for EMI (electromagnetic noise) countermeasure, allows a resonant frequency to be variable by coupling the source and drain nodes of an N-type MOS transistor to a terminal for a control voltage and adjusting the control voltage is disclosed (embodiment 1 and FIG. 3 of patent document 2). Further, a configuration in which the gate node of a P-type transistor constituting a capacitor cell is coupled to a ground terminal, and the back gate thereof is coupled to a power supply terminal is disclosed (embodiment 2 and FIG. 9 of patent document 2).

In this patent document 2, there is no description and suggestion about the problem in that wirings inside capacitor cells interfere with wirings for logic integrated circuits and, as a result, a sufficient number of capacitor cells are difficult to arrange.

It is an object of the present invention to provide not only an integrated circuit that enables the solution of the foregoing problem to enable the addition of larger amount of capacitance to the integrated circuit itself so as to enable the integrated circuit itself to have high tolerance to power supply noise, but also a design method, a design apparatus, and a design program that enable the design of such an integrated circuit.

According to a first aspect of the present invention, an integrated circuit includes a default cell including a capacitance element, a power supply terminal, a ground terminal, a first wiring that couples one terminal of the capacitance element to the power supply element, and a second wiring that couples another terminal of the capacitance element to the ground terminal, and

a blank cell including only a capacitance element, a power supply terminal, and a ground terminal and configured to, when the default cell is arranged in an empty portion of the integrated circuit and a wiring of the arranged default cell is short circuited with a wiring of the integrated circuit, the blank cell is arranged instead of the arranged default cell, a wiring for coupling one terminal of the capacitance element of the blank cell to the power supply terminal of the blank cell or a wiring for coupling another terminal of the capacitance element of the blank cell to the ground terminal of the blank cell at the short circuited portion is arranged bypassing the wiring of the integrated circuit. [0012]

According to a second aspect of the present invention, a design method for an integrated circuit includes arranging a default cell including a capacitance element, a power supply terminal, a ground terminal, a first wiring that couples one terminal of the capacitance element to the power supply element, and a second wiring that couples another terminal of the capacitance element to the ground terminal, arranging the default cell in an empty portion of the integrated circuit when a wiring of the arranged default cell is short circuited with a wiring of the integrated circuit, arranging the blank cell instead of the arranged default cell, a wiring for coupling one terminal of the capacitance element of the blank cell to the power supply terminal of the blank cell or a wiring for coupling another terminal of the capacitance element of the blank cell to the ground terminal of the blank cell at the short circuited portion is arranged bypassing the wiring of the integrated circuit.

According to a third aspect of the present invention, an integrated circuit design apparatus includes an arrangement and wiring information/various kinds of library input unit configured to take in arrangement and wiring information and a physical library that are related to an integrated circuit; a design rule input unit configured to take in design rule information; a required capacitance calculation unit configured to calculate and obtain, for each of wirings of the integrated circuit, required capacitance and at least one required capacitor cell on the basis of information from the arrangement and wiring information/various kinds of library input unit and the design rule input unit; a capacitor cell addition unit configured to add the at least one required capacitor cell to the each of the wirings of the integrated circuit on the basis of the required capacitance and the at least one required capacitor cell, which have been calculated and obtained by the capacitor-cell capacitance calculation unit; a capacitor cell formation unit configured to, in a case where, in detection on whether or not each of wirings of the at least one capacitor cell having been added by the capacitor cell addition unit is short circuited with any one of at least one different wiring included in the wirings of the integrated circuit and being different from the wirings of the at least one capacitor cell having been added by the capacitor cell addition unit, a wiring of the arranged default cell is short circuited with a wiring of the integrated circuit, a blank cell including only a capacitance element, a power supply terminal, and a ground terminal is arranged instead of the arranged capacitor cell, a wiring for coupling one terminal of the capacitance element of the blank cell to the power supply terminal of the blank cell or a wiring for coupling another terminal of the capacitance element of the blank cell to the ground terminal of the blank cell at the short circuited portion and a total capacitance calculation unit configured to compare the required capacitance having been calculated by the required capacitance calculation unit with total capacitance of capacitance of at least one finally arranged capacitor cell among the at least one capacitor cell having been added by the capacitor cell addition unit and capacitance of the at least one blank cell having been arranged by the capacitor cell formation unit. total capacitance calculation

According to a fourth aspect of the present invention, a non-transitory computer-readable recording medium that records a design program performing: a process of preparing a default cell including a capacitance element, a power supply terminal, a ground terminal, a wiring that couples one terminal of the capacitance element to the power supply element, and a wiring that couples another terminal of the capacitance element to the ground terminal and a blank cell including only a capacitance element, a power supply terminal, and a ground terminal; a process of arranging the default cell in an empty portion of the integrated circuit; a process of arranging, in substitution for the arranged default cell, a process of arranging the blank cell instead of the arranged default cell when a wiring of the arranged default cell is short circuited with a wiring of the integrated circuit, a process of arranging a wiring for coupling one terminal of the capacitance element of the blank cell to the power supply terminal of the blank cell or a wiring for coupling another terminal of the capacitance element of the blank cell to the ground terminal of the blank cell at the short circuited portion bypassing the wiring of the integrated circuit.

The integrated circuit, the design method for an integrated circuit, the integrated circuit design apparatus, and the design program for an integrated circuit according to the present invention enable the addition of larger amount of capacitance even in portions where general signal wirings interfere with the metallic constituent elements of capacitor cells and, as a result, a sufficient number of capacitance cells are difficult to arrange, and thus, enable the design of an integrated circuit having high tolerance to power supply noise.

### BRIEF DESCRIPTION OF THE DRAWINGS

FIG. 1 is a block diagram illustrating an LSI design apparatus according to a first embodiment of the present invention.

FIG. 2 is a flowchart illustrating LSI design steps according to the first embodiment of the present invention.

FIG. 3 is a schematic plan view of a default cell according to the first embodiment of the present invention illustrating an example of wirings inside the default cell.

FIG. 4 is a schematic plan view of the default cell illustrating an example in which wirings inside the default cell are short circuited with wirings of an LSI.

FIG. 5 is a schematic plan view of a blank cell used in the first embodiment of the present invention.

FIG. 6 is a schematic plan view of the blank cell according to the first embodiment of the present invention illustrating a state in which, in the blank cell, a GND terminal is coupled to a drain GND wiring using a metal second layer.

FIG. 7 is a schematic plan view of the blank cell according to the first embodiment of the present invention illustrating a state in which, in the blank cell, a gate node is coupled to a VDD terminal using trunk lines.

FIG. 8 is a schematic plan view of the blank cell according to the first embodiment of the present invention illustrating a state in which, in the blank cell, trunk lines are coupled to one another using branch lines.

FIG. 9 is a schematic plan view of the blank cell according to the first embodiment of the present invention illustrating a state in which, in the blank cell, when a wiring in a metal first layer runs in parallel to and adjacent to a VDD terminal, trunk lines are unable to be drawn out from the VDD terminal.

FIG. 10 is a diagram illustrating “Capacitance of Typical 4 μm Silicon Gate CMOS Process” described in non-patent document 1.

FIG. 11 is a schematic plan view of a blank cell describing a second embodiment of the present invention.

FIG. 12 is a diagram that describes a third embodiment of the present invention.

### DESCRIPTION OF THE EXAMPLE EMBODIMENTS

### First Example Embodiment

### Description of Configuration

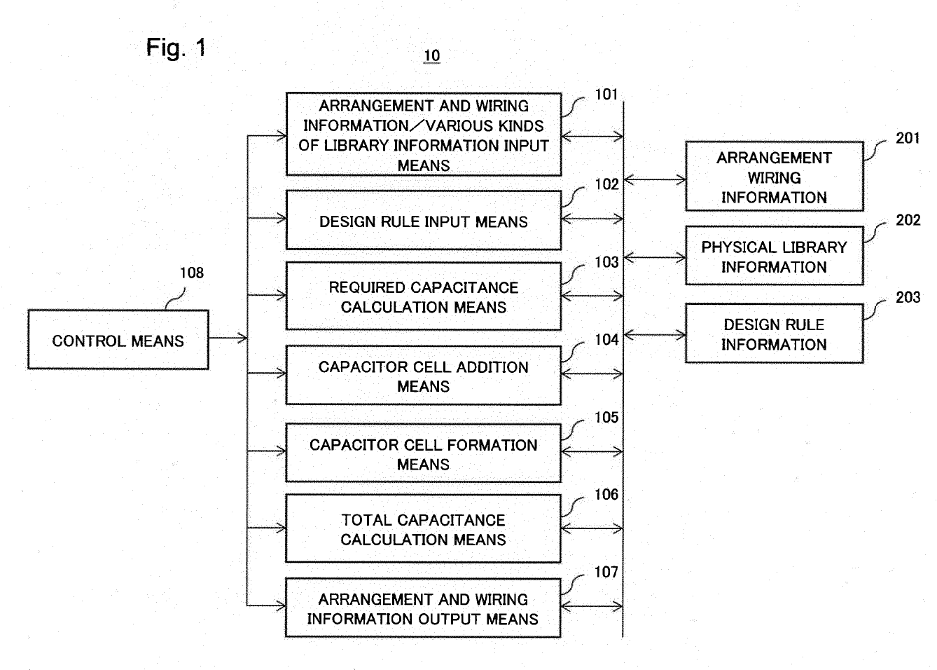

Hereinafter, a first example embodiment of the present invention will be described using the figures. FIG. 1 is a block diagram illustrating an LSI design apparatus 10 according to this first embodiment. An LSI of this embodiment is a logic integrated circuit designed using a standard cell method. The LSI design apparatus 10 includes, at minimum, an arrangement and wiring information/various kinds of library information input means 101, a design rule input means 102, a required capacitance calculation means 103, a capacitor cell addition means 104, capacitor cell formation means 105, a total capacitance calculation means 106, an arrangement and wiring information output means 107, and a control means 108.

The arrangement and wiring information/various kinds of library information input mean 101 takes in information needed for layout design of an LSI, such as arrangement and wiring information 201, which is related to the LSI, and physical library information 202. The arrangement and wiring information 201 includes information in relation to the functions and the arrangements, wiring information, and any other information with respect to blocks, such as an arithmetic and logic unit (ALU), an adder circuit, and a memory, and is input by an LSI designer.

The physical library information 202 is stored in a storage device or a memory inside the LSI design apparatus 10, or is taken from the outside of the LSI design apparatus 10. Further, the arrangement and wiring information/various kinds of library information input mean 101 divides the LSI into regions each being an appropriate handling unit, such as a function block. Hereinafter, the arrangement and wiring information/various kinds of library information input mean 101 will be abbreviated and referred to as a wiring/library information input means 101.

The design rule input means 102 takes in design rule information 203. This design rule information 203 is used in calculation of required capacitance during the LSI layout design. The design rule information 203 is stored in a storage device or a memory in the LSI design apparatus 10, or is input by the LSI designer.

For each of the regions having been divided by the wiring/library information input means 101, the required capacitance calculation means 103 calculates capacitance and capacitor cells that are required to cause the LSI not to generate noise or is required to absorb noise generated by the LSI, and determines wirings into which the capacitor cells should be inserted, referring to the arrangement and wiring information and the design rules.

Based on the required capacitance that have been calculated for each of the divided regions by the required capacitance calculation means 103, the capacitor cell addition means 104 adds capacitor cells each including a wiring pattern to empty portions inside the each of the divided regions until the required capacitance is satisfied. Since this is the addition of a capacitor, the capacitor cell is added to an empty portion in a wiring region, that is, an empty portion in which any element, such as a transistor, does not exist under a target wiring.

The capacitor cell formation means 105 detects whether or not each of wirings of each of default cells having been added by the capacitor cell addition means 104 is short circuited with any one of general wirings of the LSI that have been taken in by the wiring/library information input means 101. That is, the capacitor cell formation means 105 detects whether or not, when each of the default cells is added as it is, each of wirings inside the each of the default cells is brought into contact with and short circuited with any one of general wirings running in the same region as that of the each of the default cells.

In the case where at least one of the wirings inside the each of the default cells is short circuited with any one of the general wirings, a capacitor cell including only VDD and GND terminals (hereinafter, this kind of capacitor cell being referred to as a blank cell) is arranged. After this arrangement, a capacitor cell is formed by performing metallic wirings with respect to the inside of the blank cell so as not to allow the metallic wirings to be short circuited with any one of general signal wirings in the form of allowing the gate node of a transistor inside the blank cell to be coupled to the VDD terminal of the blank cell and allowing the source and the drain nodes of the transistor to be coupled to the GND terminal of the blank cell (hereinafter, this kind of capacitor cell being referred to as a customized cell).

The total capacitance calculation means 106 performs addition of the capacitance corresponding to finally arranged default cells among the default cells having been added by the capacitor cell addition means 104, the capacitance corresponding to finally arranged blank cells among the blank cells having been added by the capacitor cell formation means 105, and the capacitance corresponding to the customized cells having been formed by the capacitor cell formation means 105, and compares the total capacitance resulting from the addition with the required capacitance, which is to be formed by capacitor cells arranged in each of the divided regions and which has been calculated by the required capacitance calculation means 103.

The arrangement and wiring information output means 107 outputs arrangement and wiring information in relation to the LSI resulting from the addition of the capacitor cells.

The control means 108 controls the above-described series of processes. Here, the direction of each of arrows in FIG. 1 indicates just an example, and does not limit the direction of the signal between relevant blocks.

### Description of Operation

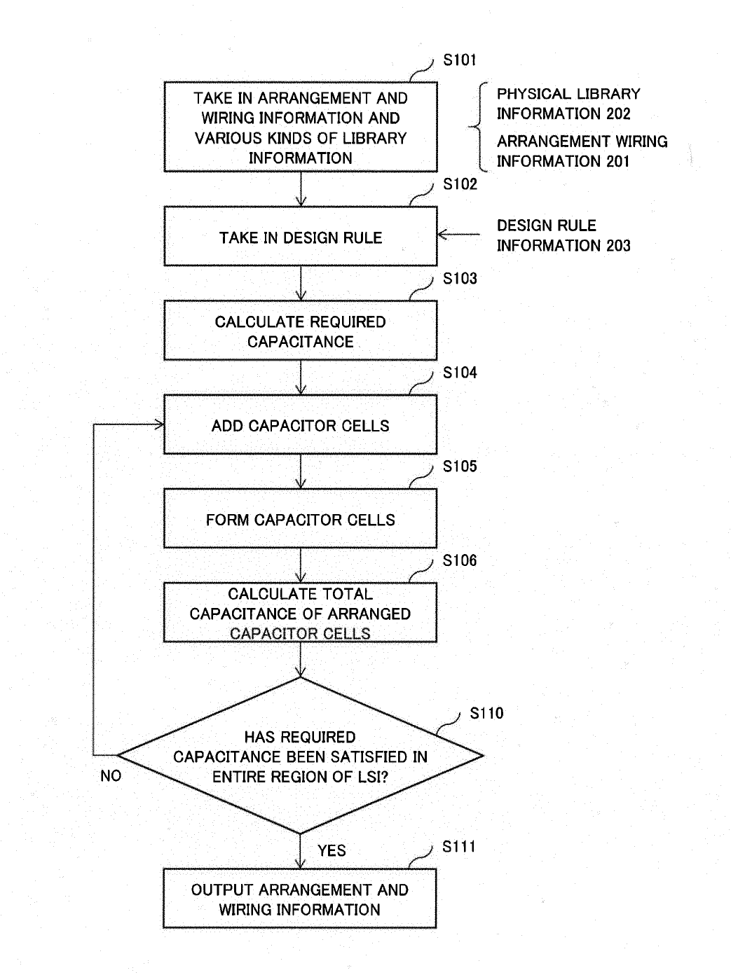

The operation of the LSI design apparatus 10 according to the first embodiment will be described referring to a flowchart (FIG. 2) illustrating the LSI design steps according to the first embodiment.

First, the wiring/library information input mean 101 takes in information needed for LSI layout design, such as the arrangement and wiring information 201, which is related to an LSI, and the physical library information 202 (S101). Further, the wiring/library information input mean 101 divides the LSI into regions each being an appropriate handling unit, such as a function block.

Next, the design rule input means 102 takes in the design rule information 203, which is used for calculation of required capacitance during the LSI layout design. (S102).

Next, the required capacitance calculation means 103 calculates the required capacitance for each of the divided regions of the LSI, referring to the arrangement and wiring information, which has been taken in by the wiring/library information input means 101, and the design rules, which have been taken in by the design rule input means 102 (S103).

With respective to the calculation of the required capacitance, for example, a technology disclosed in patent document 3 (Japanese Unexamined Patent Application Publication No. 2002-288253) is applicable thereto. Through the process in step S103, the required capacitance are calculated for each of regions having been determined in accordance with a matrix of power supply wirings that are longitudinally and laterally arranged inside the LSI (i.e., a power grid), and any other factor. An outline method for calculating the required capacitance will be described below.

A two-dimensional plan of an integrated circuit is drawn up.

The two-dimensional plan is defined by a hardware description language. A power grid (a matrix of power supply wirings) is superposed on this two-dimensional plan, and the superposed two-dimensional plan and power grid are divided into a plurality of regions. For each of the divided regions, a support decoupling capacitance value required to maintain the voltage of the power grid is determined. A specific capacitance value for each of the regions is determined. The specific capacitance value is a specific capacitance value in accordance with the size of the each of the regions, and any other factor.

A required decoupling capacitance value is determined on the basis of these support decoupling capacitance value and specific capacitance value.

The required decoupling capacitance value for each of the regions is determined by subtracting the support decoupling capacitance value from the specific capacitance value.

Next, a decoupling capacitor area corresponding to the required decoupling capacitance value is determined. The position of a circuit area in each of the regions is corrected on the basis of the decoupling capacitor area.

Next, based on the required capacitance that have been calculated by the required capacitance calculation means 103, the capacitor cell addition means 104 adds capacitor cells each including a wiring pattern to empty portions included in each of the divided regions and having likewise been determined by the design rule input means 102 until the required capacitance is satisfied (S104). The capacitor cell is constituted by forming interconnection between the gate node of a transistor disposed in the cell and a VDD (power supply voltage) terminal and interconnection between the drain node of the transistor and a GND (ground) terminal through metallic wirings and contacts, and has fixed amount of capacitance determined by the width and length of each of the wirings. Hereinafter, a capacitor cell including a wiring pattern will be referred to as a default cell.

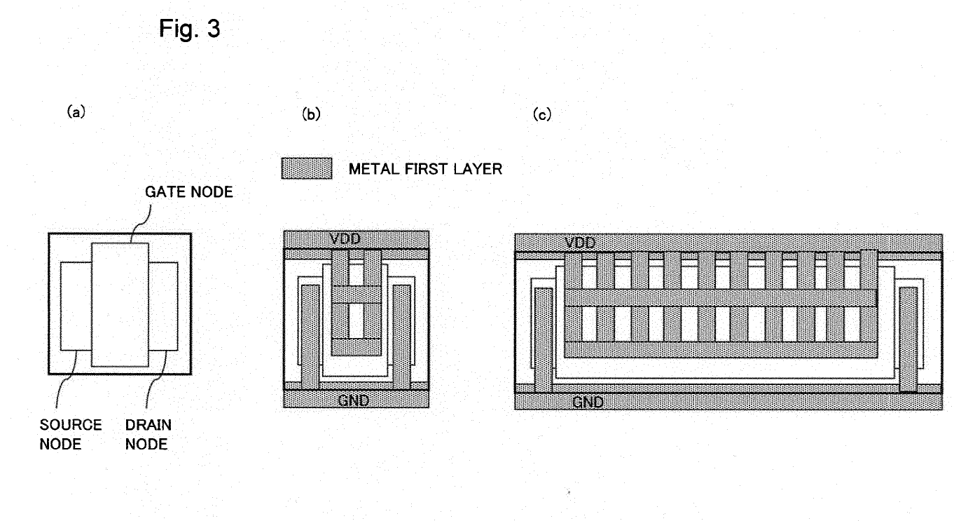

An example of wirings in the default cell is illustrated in FIG. 3. FIG. 3(a) is a schematic plan view of a MOSFET including a source node, a gate node, and a drain node and does not depict a wiring. FIG. 3(b) is a schematic plan view of a default cell in which the source node, the drain node, and the gate node shown in FIG. 3(a) are respectively coupled to GND, GND, and a power supply voltage VDD. The size of the default cell is variable in accordance with the amount of required capacitance. FIG. 3(b) illustrates a default cell 100. This default cell 100 is a minimum unit of the default cell. FIG. 3(c) is a schematic plan view of a default cell 100′. This default cell 100′ has capacitance five to six times larger than that of the default cell 100 shown in FIG. 3(b). The default cells shown in FIGS. 3(b) and 3(c) and default cells each having an area, a size, and capacitance between the area, the size, and the capacitance of the default cell shown in FIG. 3(b) and those of the default cell shown in FIG. 3(c) are retained in advance as part of the physical library information 202. According to the area and the size of a wiring empty region and a necessary additional capacitance in which the default cell is intended to be disposed, a default cell with an appropriate area, dimensions and capacitance should be choosed from the physical library information 202. The calculation of the capacitance and capacitor cells in step S103 described above is to calculate how many of which kind of default cells are to be selected and added, on the basis of the area of an empty region in which the default cells are intended to be added and additional capacitance needed in the empty region.

The wirings are constituted by a metal first layer. Here, for the sake of simplification, the description using figures about constituent elements other than metal layers will be omitted.

Next, the capacitor cell formation means 105 detects whether or not each of wirings inside each of the default cells having been added by the capacitor cell addition means 104 is short circuited with any one of the wirings of the LSI that have been taken in by the wiring/library information input means 101. In the case where at least one of wirings inside a default cell among the added default cells is short circuited with any one of the wirings of the LSI, a capacitor cell (blank cell) including only VDD and ground terminals is disposed in substitution for the default cell. After this arrangement, a capacitor cell is formed by performing metallic wirings with respect to the inside of the blank cell so as not to allow the metallic wirings to be short circuited with any one of general signal wirings in the form of allowing the gate node of a transistor inside the blank cell to be coupled to the VDD terminal of the blank cell and allowing the source and the drain nodes of the transistor to be coupled to the GND terminal of the blank cell (hereinafter, this kind of capacitor cell being referred to as a customized cell). Here, for the blank cell, similarly to the default cell, blank cells having various areas, sizes, and amounts of capacitance are preferred to be retained in advance as part of the physical library information 202 so as to enable an appropriate blank cell to be selected in accordance with requirements from among the retained blank cells.

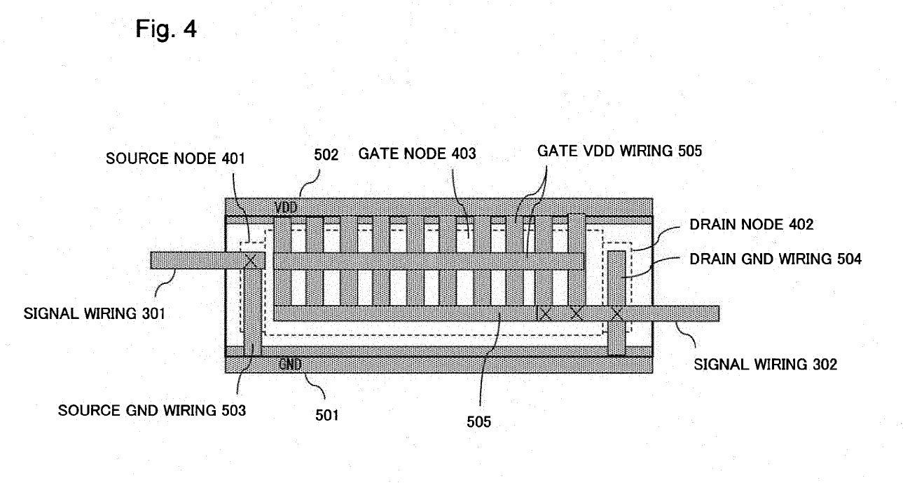

As specific description, first, an example in which wirings inside a default cell are short-circuited with wirings of LSI (two signal wirings) is illustrated in FIG. 4. In FIG. 4, portions denoted by “x” are portions at which the short circuits occur. All of a ground terminal 501, a source GND wiring 503, a drain GND wiring 504, a VDD terminal 502, gate VDD wirings 505, and signal wirings 301 and 302 are disposed on the same layer (the metal first layer).

Here, actually, for example, an insulating layer (not illustrated) is disposed between the source GND wiring 503 and a source node 401, and a via-hole (not illustrated) is provided in the insulating layer at a position where the source GND wiring 503 and the source node 401 overlap with each other in a top view, and the source GND wiring 503 and the source node 401 are coupled to each other through the via-hole. The via-hole is not illustrated in FIG. 4. Similarly, the drain GND wiring 504 and a drain node 402 sandwiches an insulating layer therebetween and are coupled to each other via a via-hole provided in the insulating layer, and the gate VDD wiring 505 and a gate node 403 sandwiches an insulating layer therebetween and are coupled to each other via a via-hole provided in the insulating layer.

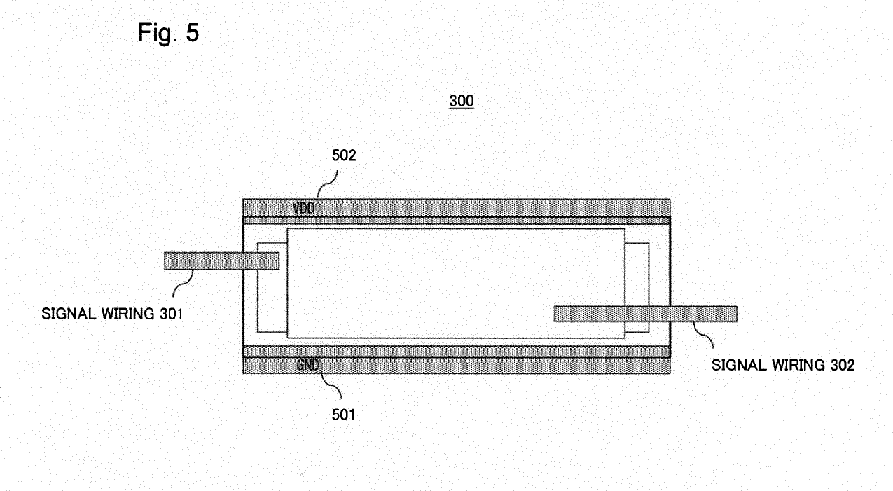

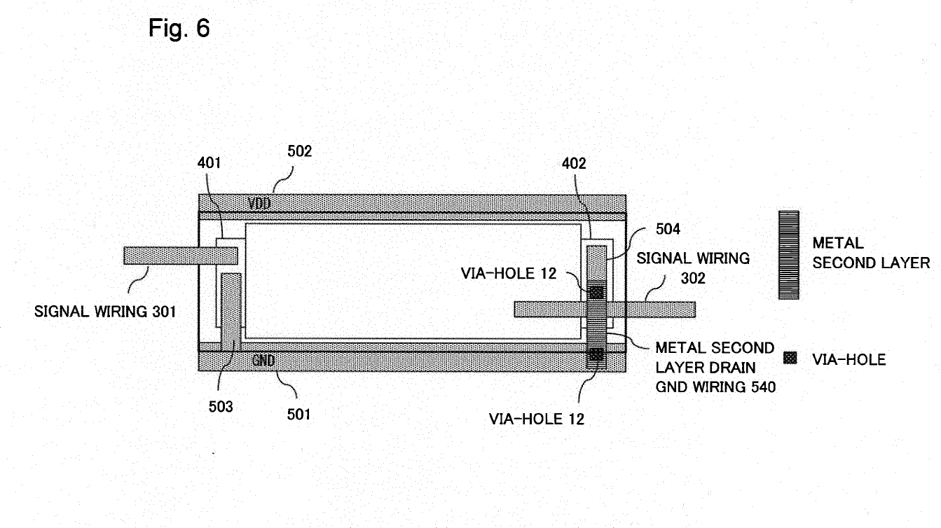

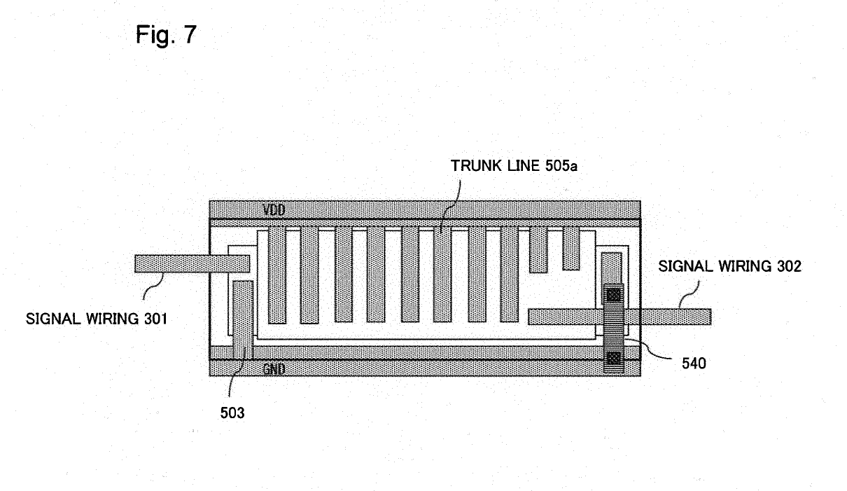

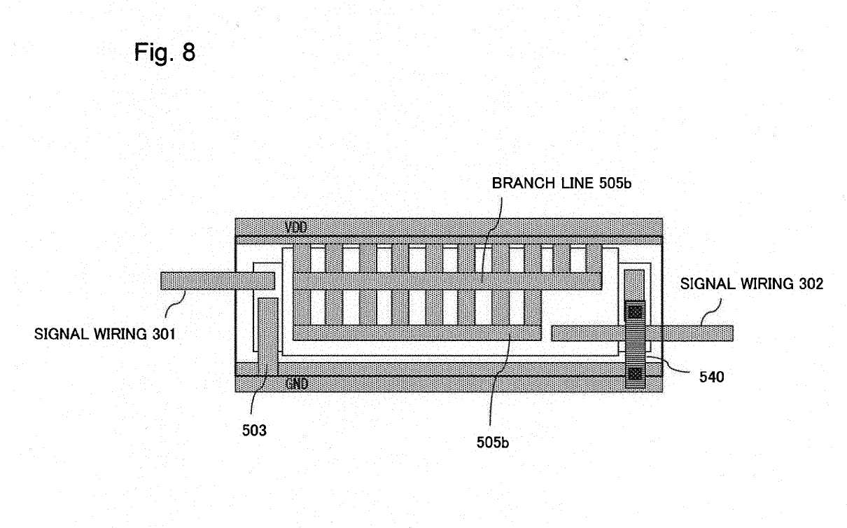

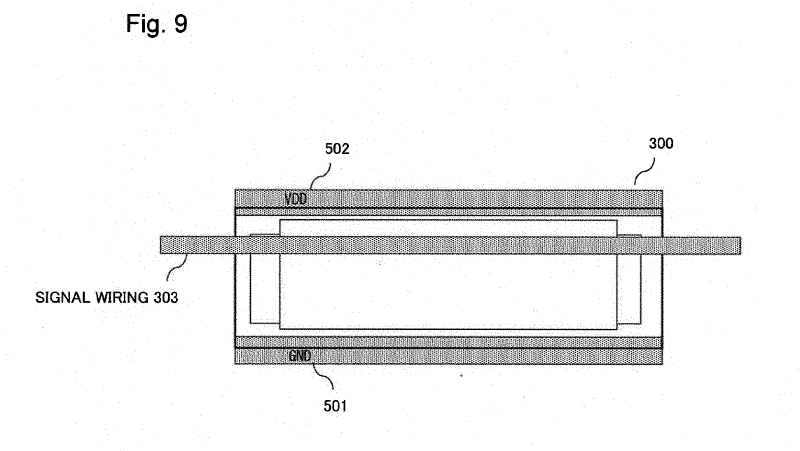

When wirings are attempted to be arranged so as to allow the source GND wiring 503 to extend from the GND terminal 501 to allow the GND terminal 501 to be electrically coupled to the source node 401, the source GND wiring 503 is short circuited with the signal wiring 301. Further, when wirings are attempted to be arranged so as to allow the drain GND wiring 504 to extended from the GND terminal 501 to allow the GND terminal 501 to be electrically coupled to the drain node 402, the drain GND wiring 504 is also short circuited with the signal wiring 302. Moreover, when wirings are attempted to be arranged so as to allow the gate VDD wirings 505 (including trunk lines and branch lines as described later) to extend from the VDD terminal 502 to allow the VDD terminal 502 to be electrically coupled to the gate node 402, the signal wiring 302 is also short circuited with the gate VDD wirings 505. The details of a bypass method according to the present embodiment will be described below using FIGS. 5 to 8.

[1] First, a blank cell 300, the signal wiring 301, and the signal wiring 302 are arranged in a relevant region (FIG. 5).

[2] When attempting to couple the GND terminal 501 of the blank cell 300 to the source node 401 and the drain node 402 using the metal first layer, as a result, a wiring coupled to the GND terminal 501 is short circuited with the signal wiring 302, as shown in FIG. 4. In order to avoid the short circuit, as shown in FIG. 6, a metal second layer (a metal second layer drain GND wiring 540) is disposed. This metal second layer drain GND wiring 540 is configured to cross over the signal wiring 302, which is constituted by the metal first layer, to electrically couple the GND terminal 501 to the drain GND wiring 504. One of via-holes 12 electrically couples the metal second layer drain GND wiring 540 to the GND terminal 501, and the other one of the via-holes 12 electrically couples the metal second layer drain GND wiring 540 to the drain GND wiring 504. The via-holes 12 are wirings for electrically coupling the metal first layer to the metal second layer in a layer-thickness direction.

[3] Similarly, the VDD terminal 502 of the blank cell 300 is electrically coupled to the gate node 403 so as to avoid the contact with the signal wiring 302. As a specific coupling method, trunk lines 505a of the gate VDD wiring are allowed to extend from the VDD terminal in a longitudinal direction of FIG. 7, and next, branch lines 505b are formed so as to extend in a lateral direction of FIG. 8 to interconnect the trunk lines 505a. If a wiring target layer is expanded to the second layer, a wiring period of time is increased, and thus, in this case, the trunk lines 505a and the branch lines 505b are formed using only the metal first layer. Here, in FIG. 8, the trunk lines 505a and the branch lines 505b look like two kinds of lines intersecting with each other, but this is just a matter on design data, and physically, the trunk lines 505a and the branch lines 505b are two kinds of metallic lines on the same layer.

[4] In the case where the GND terminal of the blank cell is unable to be coupled to the source and the drain nodes in [2] above, and/or in the case where the trunk lines for coupling the VDD terminal of the blank cell to the gate region of the blank cell are unable to be drawn out in [3] above, that is, in the case where a configuration serving as a decoupling capacitor is unable to be made, any further process is not performed. That is, the blank cell 300 is made remain in a state of being disposed. For example, as shown in FIG. 9, in the case where a wiring (here, a signal wiring 303) on the metal first layer runs in parallel to and adjacent to the VDD terminal 502, the trunk lines to be extended in a longitudinal direction of FIG. 9 are unable to be drawn out from the VDD terminal 502. In this case, therefore, the blank cell remains as it is.

Next, the total capacitance calculation means 106 performs addition of the capacitance of finally arranged default cells among the default cells having been added by the capacitor cell addition means 104, the capacitance of finally arranged blank cells among the blank cells having been added by the capacitor cell formation means 105, and the capacitance of the customized cells having been formed by the capacitor cell formation means 105, and compares total capacitance obtained by the addition with the required capacitance, which has been calculated for each of the divided regions by the required capacitance calculation means 103.

When the required capacitor is not obtained through the above steps, the addition of capacitor cells by the capacitor cell addition means 104 and the subsequently performed capacitor cell formation by the capacitor cell formation means 105 are carried out once again in a different empty portion inside wirings having been determined by the required capacitance calculation means 103.

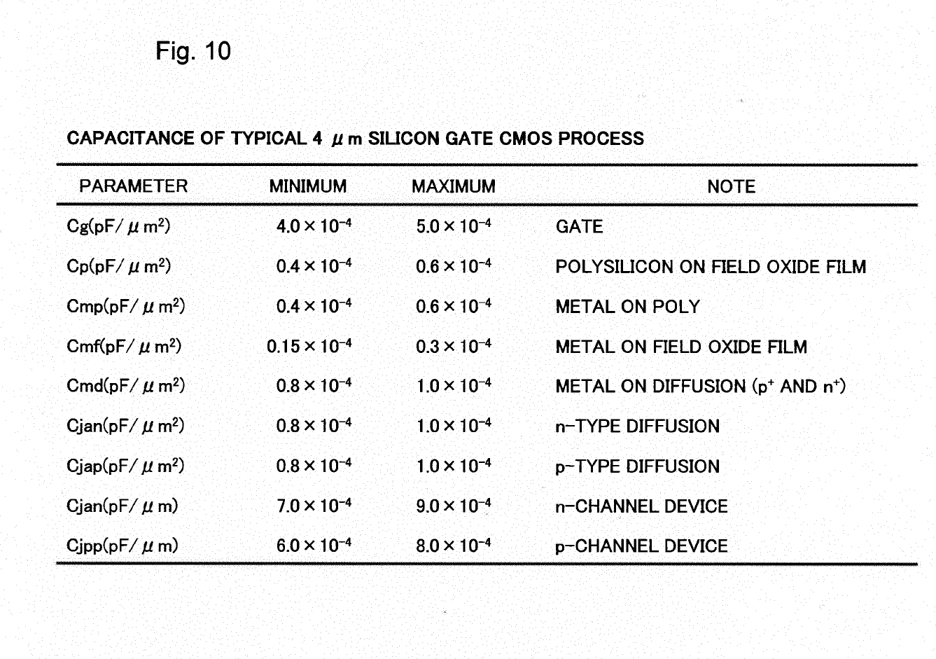

The default cells and the blank cells have their specific capacitance values in accordance with their sizes, and the capacitance values are taken in by the wiring/library information input means 101 as already determined values at the time of the design of cells. An example of the capacitance values is indicated in a related document, that is, non-patent document 1 (“Principles of CMOS VLSI design: a system perspective”, second edition, Maruzen Co., Ltd., ISBN 4-621-03294-1, p. 115, table 4.5 “Capacitance of Typical 4 μm Silicon Gate CMOS Process”). Here, the capacitance values of individual constituent elements in a 4 μm gate process are defined (FIG. 10), and each of the capacitance values is proportional to the area of a corresponding one of the constituent elements. Upon determination of the area of each of constituent elements, the capacitance value of the each of constituent elements is also uniquely determined, and thus, finally, the capacitance value of a cell is defined as a capacitance value specific to the cell.

The capacitance of the customized cell includes parasitic capacitance formed between the metal first layer and polysilicon (polycrystalline silicon), in addition to the previously described capacitance constituent elements of the blank cell 300. The amount of the parasitic capacitance is proportional to the area of overlapping portions between the wirings of the metal first layer and a gate face, and a specific example is shown in FIG. 10, such as: the capacitance value of “metal on poly.” is at minimum 0.4×10⁻⁴ pF/μm² and at maximum 0.6×10⁻⁴ pF/μm²″. The parasitic capacitance is obtained by multiplying the area of the wirings of the metal first layer, which have been arranged by the capacitor cell formation means 105, by the above value. The value of the calculated parasitic capacitance is provided by the wiring/library information input means 101 as information needed for the LSI layout design. Here, “CMOS” in FIG. 10 is the abbreviation of a complementary MOS, and “poly.” is the abbreviation of polysilicon. Further, “diffusion” is the abbreviation of a diffusion layer, and means a layer that is formed by doping impurities into silicon and serves as a layer for a source node, a drain node, or any other node.

When the capacitor cells have been inserted into all empty portions of regions included in the entire region of the LSI and having been determined by the required capacitance calculation means 103, and the required capacitance has been satisfied (YES in step S110), arrangement and wiring information in relation to the LSI in which the on-chip capacitor cells have been added is output by the arrangement and wiring information output means 107 (S111).

When, however, the required capacitance is not satisfied (NO in step S110), the addition of capacitor cells (the capacitor cell addition means 104), the formation of the capacitor cells (the capacitor cell formation means 105), and the calculation of the capacitance of the capacitor cells (the total capacitance calculation means 106) are repeated until the required capacitance is satisfied.

### Description of Advantageous Effects

In the method having been described in the background art, there are portions where general signal wirings interfere with the metallic constituent elements of capacitor cells and, as a result, a sufficient number of capacitance cells are difficult to arrange. The above configuration in the present embodiment enables the addition of larger amount of capacitance, and thus, enables the design of an LSI having high tolerance to power supply noise.

Here, in the present embodiment, as shown in FIG. 6, when the GND terminal 501 is coupled to the drain 402, the via-holes 12 and the metal second layer are used, and further, a case where via-holes and the metal second layer are used when the GND terminal 501 is coupled to the source node 401 also occurs if the signal wiring 301 is located so as to interfere with the coupling of the GND terminal 501 to the source node 401. Moreover, a case where via-holes and the metal second layer are used in both of the drain node and the source node may also occur. It is obvious that these configurations are also included in the scope of the present invention.

Further, in the present embodiment, a wiring that is short circuited with the drain GND wiring signal is a signal wiring. In this regard, however, even when the wiring that is short circuited with the drain GND wiring signal is a wiring other than the signal wirings, that is, even when the wiring is short circuited with, for example, a power supply wiring different from the power supply wirings including the above respective VDD terminal 502 and GND terminal 501, the present invention is applicable to this configuration.

### Second Example Embodiment

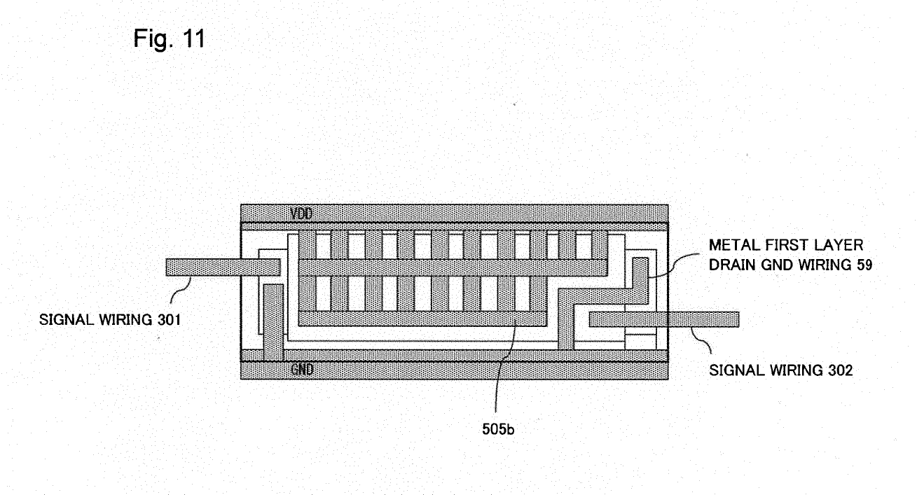

In the first example embodiment, the second layer drain GND wiring 540 is used to bypass the signal wiring 302. In this case, however, if a configuration is made such that a space is provided so as to allow the first layer metal wiring to be arranged between the signal wiring 302 and lines composed of the trunk lines 505a and the branch lines 505b, as shown in FIG. 11, this configuration enables the metal first layer drain GND wiring 590 to pass through the space.

### Third Example Embodiment

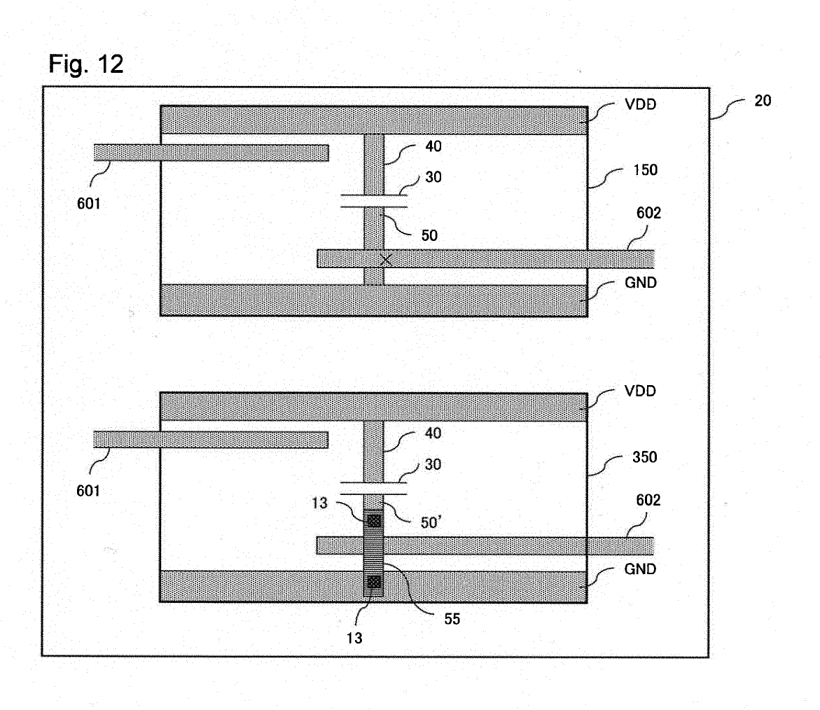

A third example embodiment of the present invention will be described using FIG. 12. A default cell 150 is a cell in which a wiring 40 coupled to one of nodes of a capacitance element 30 is coupled to the power supply terminal VDD through a wiring, and a wiring 50 coupled to the other one of the nodes of the capacitance element 30 is coupled to the ground terminal GND through a wiring. Further, a blank cell 350 is a cell including only the power supply terminal VDD and the ground terminal GND. The default cell 150 is disposed in an empty portion of an integrated circuit 20. There is a case where different wirings 601 and 602 other than a target wiring to which the default cell 150 is to be coupled, and to which the capacitance element 30 is to be added, run in the integrated circuit 20. In FIG. 12, the different wiring 602 is short circuited with the wiring 50, which is coupled to the other one of the nodes of the capacitance element 30. In FIG. 12, “x” denotes the short circuit.

When such a short circuit occurs, the blank cell 350 is disposed in substitution for the default cell 150. In the disposed blank cell 350, a wiring layer 55 is disposed as an upper wiring layer located above the different wiring 602 so as to allow a wiring between the capacitance element and the power supply terminal or the ground terminal in a short-circuited portion to bypass the different wiring 602. A wiring 50′ is disposed so as to allow one end of the wiring layer 55 to be coupled to the other one of the nodes of the capacitor cell via-hole 13, and similarly, the other end of the wiring layer 55 is coupled to the GND terminal through a via-hole 13.

This configuration enables the addition of larger amount of capacitance, and thus, enables the design of an LSI having high tolerance to power supply noise.

### Other Example Embodiments

In the first and second example embodiments, the source and drain nodes of the MOSFET are coupled to GND, and the gate node thereof is coupled to VDD to form a capacitance element. However, configurations other than such a configuration in which a capacitance element is formed from the MOSFET enable the formation of a capacitance element in an LSI. For example, the configuration in which a capacitance element is formed by a lamination structure of a metallic material, an insulating layer, and a metallic material may be employed. A cell including only this capacitance element, a VDD terminal, and a GND terminal may be handled as a blank cell, and a cell in which a wiring that couples the VDD terminal to one of the electrodes of the capacitance element, and a wiring that couples the GND terminal to the other one of the electrodes thereof are arranged may be handled as a default cell.

Further, for the simplification of the calculation, in the case where the width of each of wirings is fixed, a capacitance value per a unit of area is handled as a wiring capacitance value per a unit of wiring length, and the capacitance value of a wiring may be calculated in a simple manner, that is, by multiplying the length of the wiring by the wiring capacitance value per a unit of wiring length.

Further, an LSI design apparatus according to the first to third embodiments may be configured using a dedicated apparatus, but the LSI design apparatus is achieved by using a computer (an information processing apparatus).

In this case, the computer retrieves a design program stored in a memory (not illustrated) into a central processing unit (CPU) (not illustrated), and allows the CPU to execute the retrieved software program. Moreover, it is understood that a storage medium in which such a program is stored and from which the stored program is readable by a computer also constitutes the present invention.

### INDUSTRIAL APPLICABILITY

The present invention is applicable to layout design of a semiconductor logic integrated circuit that is designed using MOSFETs by means of a standard cell method, a gate array method, or any other suitable design method. The previous description of embodiments is provided to enable a person skilled in the art to make and use the present invention. Moreover, various modifications to these exemplary embodiments will be readily apparent to those skilled in the art, and the generic principles and specific examples defined herein may be applied to other embodiments without the use of inventive faculty. Therefore, the present invention is not intended to be limited to the exemplary embodiments described herein but is to be accorded the widest scope as defined by the limitations of the claims and equivalents. Further, it is noted that the inventor's intent is to retain all equivalents of the claimed invention even if the claims are amended during prosecution.

### REFERENCE SIGNS LIST

10 LSI design apparatus
12 and 13 via-hole
30 capacitance element
40 wiring coupled to one of nodes of a capacitance element.
50 and 50′ wiring coupled to the other one of nodes of a capacitance element
100 and 150 default cell
101 arrangement and wiring information/various kinds of library information input means
102 design rule input means
103 required capacitance calculation means
104 capacitor cell addition means
105 capacitor cell formation means
106 total capacitance calculation means
107 arrangement and wiring information output means
108 control means
201 arrangement and wiring information
202 physical library information
203 design rule information
300 and 350 blank cell
301, 302, and 303 signal wiring
401 source node
402 drain node
403 gate node
501 ground terminal
502 VDD terminal
503 source GND wiring
504 drain GND wiring
505 gate VDD wiring
505a trunk line
505b branch line
540 metal second layer drain GND wiring
590 metal first layer drain GND wiring
601 and 602 different wiring

1. An integrated circuit comprising:
a default cell including a capacitance element, a power supply terminal, a ground terminal, a first wiring that couples one terminal of the capacitance element to the power supply element, and a second wiring that couples another terminal of the capacitance element to the ground terminal, and
a blank cell including only a capacitance element, a power supply terminal, and a ground terminal and configured to, when the default cell is arranged in an empty portion of the integrated circuit and a wiring of the arranged default cell is short circuited with a wiring of the integrated circuit, the blank cell is arranged instead of the arranged default cell, a wiring for coupling one terminal of the capacitance element of the blank cell to the power supply terminal of the blank cell or a wiring for coupling another terminal of the capacitance element of the blank cell to the ground terminal of the blank cell at the short circuited portion is arranged bypassing the wiring of the integrated circuit.

2. The integrated circuit according to claim 1, wherein the wiring for coupling one terminal of the capacitance element of the blank cell to the power supply terminal of the blank cell or the wiring for coupling another terminal of the capacitance element of the blank cell to the ground terminal of the blank cell at the short circuited portion is arranged as a wiring layer different from a wiring layer for the wiring of the integrated circuit.

3. The integrated circuit according to claim 1, wherein the empty portion of the integrated circuit is included in a wiring region of the integrated circuit.

4. The integrated circuit according to claim 1, wherein the capacitance element is an element composed of a MOSFET that allows a gate node of the MOSFET to be coupled to the power supply terminal and that allows a source node and a drain node of the MOSFET to be coupled to the ground terminal.

5. The integrated circuit according to claim 1, wherein the integrated circuit is an integrated circuit based on a standard cell method.

6. A design method for an integrated circuit, comprising:
arranging a default cell including a capacitance element, a power supply terminal, a ground terminal, a first wiring that couples one terminal of the capacitance element to the power supply element, and a second wiring that couples another terminal of the capacitance element to the ground terminal,
arranging the default cell in an empty portion of the integrated circuit when a wiring of the arranged default cell is short circuited with a wiring of the integrated circuit, arranging the blank cell instead of the arranged default cell, a wiring for coupling one terminal of the capacitance element of the blank cell to the power supply terminal of the blank cell or a wiring for coupling another terminal of the capacitance element of the blank cell to the ground terminal of the blank cell at the short circuited portion is arranged bypassing the wiring of the integrated circuit.

7. The design method according to claim 6, wherein, when capacitance of the default cell or the blank cell that has been arranged does not satisfy required capacitance, the default cell or the blank cell is further arranged until the required capacitance is satisfied.

8. An integrated circuit design apparatus comprising:
an arrangement and wiring information/various kinds of library input unit configured to take in arrangement and wiring information and a physical library that are related to an integrated circuit;
a design rule input unit configured to take in design rule information;
a required capacitance calculation unit configured to calculate and obtain, for each of wirings of the integrated circuit, required capacitance and at least one required capacitor cell on the basis of information from the arrangement and wiring information/various kinds of library input unit and the design rule input unit;
a capacitor cell addition unit configured to add the at least one required capacitor cell to the each of the wirings of the integrated circuit on the basis of the required capacitance and the at least one required capacitor cell, which have been calculated and obtained by the capacitor-cell capacitance calculation unit;
a capacitor cell formation unit configured to, in a case where, in detection on whether or not each of wirings of the at least one capacitor cell having been added by the capacitor cell addition unit is short circuited with any one of at least one different wiring included in the wirings of the integrated circuit and being different from the wirings of the at least one capacitor cell having been added by the capacitor cell addition unit, a wiring of the arranged default cell is short circuited with a wiring of the integrated circuit, a blank cell including only a capacitance element, a power supply terminal, and a ground terminal is arranged instead of the arranged capacitor cell, a wiring for coupling one terminal of the capacitance element of the blank cell to the power supply terminal of the blank cell or a wiring for coupling another terminal of the capacitance element of the blank cell to the ground terminal of the blank cell at the short circuited portion and
a total capacitance calculation unit configured to compare the required capacitance having been calculated by the required capacitance calculation unit with total capacitance of capacitance of at least one finally arranged capacitor cell among the at least one capacitor cell having been added by the capacitor cell addition unit and capacitance of the at least one blank cell having been arranged by the capacitor cell formation unit.

9. The integrated circuit design apparatus according to claim 8, wherein, when the total capacitance of the capacitance of the at least one finally arranged capacitor cell and the capacitance of the at least one formed blank cell does not satisfy the required capacitance, the default cell or the blank cell is further arranged until the required capacitance is satisfied.
